(19) United States
(12) Patent Application Publication
(10) Pub. No.: US 2009/0284291 A1
(43) Pub. Date: Nov. 19, 2009

(54) COMPLEMENTARY SIGNAL GENERATION CIRCUIT AND SEMICONDUCTOR DEVICE COMPRISING SAME

(75) Inventor: Kazuhiro TERAMOTO, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/465,823

(22) Filed: May 14, 2009

(30) Foreign Application Priority Data
May 16, 2008 (JP) 2008-129959

(51) Int. Cl. H03L 7/06; H03K 7/08; H03H 11/26

(52) U.S. Cl. 327/158; 327/171; 327/290

(57) ABSTRACT

A complementary signal generation circuit includes a first transmission path including a first number N of inverters and a second transmission path including a second number (N−1) of inverters. A delay circuit composed of a first resistance element and a capacity element is arranged in series between two inverters in the second transmission path so as to correspond to any one of the inverters in the first transmission path. The capacity element is formed by a capacitive inverter having the same input capacity ratio as the any one of the inverters. The complementary signal generation circuit generates output signals having the logic levels which are complementary to each other through the first and second transmission paths.

This application is based upon and claims the benefit of priority from Japanese patent application No. 2008-129959, filed on May 16, 2008, the disclosure of which is incorporated herein in its entirety by reference.

### BACKGROUND OF THE INVENTION

1. Field of the Invention

This invention relates to a complementary signal generation circuit and a semiconductor device comprising the same.

2. Description of Related Art

A complementary signal generation circuit is a circuit which generates two output signals having opposite phases from one input signal, and is used for generating input clocks in a circuit operating in accordance with complementary clock signals, such as a tristate buffer or a flip-flop.

FIG. 5 shows a latch circuit as an example applying complementary signals. Control signals φ and /φ are complementary signals having mutually opposite phases. In the description below, the low level of a signal is sometimes represented as “L”, and the high level is sometimes represented as “H”.

This latch circuit operates as an inverter when the control signal φ is “L” (the control signal /φ is “H”), whereas when the control signal φ is “H” (the control signal /φ is “L”), the latch circuit does not transmit information of an input IN to an output OUT and holds data of the output OUT. In such a circuit, timing relationship is important between the input IN and output OUT and the control signals φ and /φ. Specifically, the input signal IN must be stable when the control signals φ and /φ transit (setup time), and the input signal IN must be held until the transition of the control signals φ and /φ is completed (hold time). Any skew difference between the control signals φ and /φ will increase the setup time and the hold time. Therefore, the skew difference between the control signals φ and /φ is desirably as small as possible. The term “skew” means a period of time required to transmit a signal from the input to the output.

In recent years, in particular, the clock frequency has been increased along with enhancement of system performance, and thus a more accurate skew adjustment is required. For example, a DDR (Double Data Rate) type SDRAM (Synchronous Dynamic Random Access Memory), which is a semiconductor device composed of a field-effect transistor (FET) and so on, employs a DLL (Delay-Locked-Loop) circuit for synchronizing data output with an external clock signal.

A DLL circuit is a circuit designed to delay an external clock for a certain period of time before outputting the same. Complementary output signals from the DLL circuit are used as control clock signals for a latch circuit, so that data output of the latch circuit is controlled in synchronization with the control clock signals. In this case, in the latch circuit shown in FIG. 5, the control signals φ and /φ are the complementary signals output by the DLL circuit, and the input signal IN is data signal read out from internal memory cells.

While the DLL circuit outputs synchronized complementary signals, such a technique is often used in the DLL circuit that the input signal is transmitted as a single-phase signal inside the circuit and output as the complementary signals. A complementary signal generation circuit is employed for generating these control signals φ and /φ. The frequency of these complementary signals is as high as more than 1 GHz.

FIG. 6 shows relationship between skew and frequency f of the control signals (hereafter, referred to as the “complementary clock signals”) φ and /φ. When the frequency f is 1 GHz, the cycle tCK(=1/f) of the complementary clock signals φ and /φ is 1 ns (nanosecond). Since the data must be held for the period of time tSKEW while the complementary clock signals φ and /φ are in transit, the data signal can be changed only in the period indicated by tVALID. When the ratio of H and L periods of the complementary clock signals φ and /(φ is 1:1, the period tVALID is about (1/2)*tCK−tSKEW=500 ps−tSKEW. If it is assumed here that there is a skew difference of 50 ps (picosecond) between the complementary clock signals φ and /φ, the period tVALID is only about 450 ps. Since the clocks actually have a jitter (fluctuation), the period tVALID will be still shorter. Under such circumstances, it is requisite to minimize the time tSKEW as much as possible (to the order of several ps).

A complementary signal generation circuit generally employs either a capacity element or a transfer gate as means for adjusting the skew. An example of using a capacity element for the skew adjustment is disclosed in Japanese Laid-Open Patent Publication No. H11-26593 (Patent Document 1).

### SUMMARY

Referring to FIGS. 7 and 8, description will be made of operation and problems of complementary signal generation circuit using a capacity element. FIG. 7 is a circuit diagram for explaining a related art of this invention and shows an example of a complementary signal generation circuit. FIG. 8 is a schematic timing chart of the circuit shown in FIG. 7.

As seen from FIGS. 7 and 8, when an input signal IN transits from “L” to “H”, an output signal IN_B of an inverter 101 transits from “H” to “L”. An inverter output signal IN_B is divided into two transmission paths, and in one of the paths, the signal is transmitted along the route from the output PRE_BT of an inverter 102 to the output PRE_B of an inverter 103, and then to the output OUT_T of an inverter 104, whereby an output signal OUT_T having the same phase as the input signal IN is generated. In the other transmission path, the signal is transmitted along the route from the output PRE_T of an inverter 105 to the output OUT_B of an inverter 106, whereby an output signal OUT_B having a phase inverted by 180 degrees from that of the input signal IN is output. The reference numerals 107 and 108 respectively indicate load capacity elements connected to a signal line between the inverters 105 and 106.

The skew is often defined by the propagation time at a half-amplitude point and the transition time tT of a signal (time required for the signal level to transit from 10% to 90%). The description herein will also be made on the basis of these two.

In FIG. 8, the delay time of the output signal OUT_T/OUT_B relative to the input signal IN when the input signal IN transits to “H” is represented by t1_t/t1_b, while the delay time of the output signal OUT_T/OUT_B relative to the input signal IN when the input signal IN transits to “L” is represented by t2_t/t2_b. The transition time tT of the output signal OUT_T/OUT_B when the input signal IN transits to “H” is represented by tRt/tFb, and the transition time tT of the output signal OUT_T/OUT_B when the input signal IN transits to “L” is represented by tFt/tRb, an ideal state is obtained when the following equations (1) and (2) are satisfied.

t1_t=t1_b=t2_t=t2_b (1)

tRt=tFb=tFt=tRb (2)

It is assumed here that the inverters 102, 103, 104, 105, and 106 in FIG. 7 have gate widths of l, m, n, x, and y, respectively. When the gate capacity per unit gate width of each inverter is represented by C, the gate capacities of the inverters 102, 103, 104, 105, and 106 can be represented as l*C, m*C, n*C, x*C, and y*C, respectively, since the gate capacities are proportional to the gate widths thereof. Likewise, when the conduction (ON) resistance per unit gate width of each inverter is represented by Rt, the conduction resistances of the inverters 102, 103, 104, 105, and 106 can be represented as Rt/l, Rt/m, Rt/n, Rt/x, and Rt/y, respectively, since the conduction resistances of the inverters are inversely proportional to the gate widths thereof. The combined capacity of the load capacity elements 107 and 108 is represented by C′=z*C. In this case, the signal propagation time T_t in the path from the output IN_B to the output OUT_T is represented by the following equation (3).

$$\begin{matrix}T\_t = tTR + ( Rt / l ) {m}^{*} C + tTR + ( Rt / m ) {n}^{*} C + tTR \\ = 3 tTR + {Rt}^{*} C ( m / l + n / m )\end{matrix} \qquad ( 3 )$$

In this equation, tTR indicates a time from when the output of the inverter gate becomes “H” until when the channel is formed. The time tTR is dependent on the channel length of the transistor in the inverter and not dependent on the channel width. Therefore, the time tTR assumes the same value in all the inverters 102, 103, 104, 105, and 106 having the same channel length.

On the other hand, the signal propagation time T_b in the path extending from the output IN_B to the output OUT_B is represented by the following equation (4).

$$\begin{matrix}T\_b = tTR + Rt / x ( {y}^{*} C + {C}^{′} ) + tTR \\ = 2 tTR + {Rt}^{*} C ( y / x + z / x )\end{matrix} \qquad ( 4 )$$

The difference T between the signal propagation time in the route from the output IN_B to the output OUT_T and the signal propagation time in the route from the output IN_B to the output OUT_B in the complementary signal generation circuit is represented by the following equation (5).

T=T_{—}t−T_{—}b=tTR−Rt*C(y/x+z/x−m/l−n/m) (5)

If it is assumed that the difference in the signal propagation time between the two routes is zero, that is, T=0, the following equation (6) is obtained.

tTR=Rt*C(y/x−m/l−n/m)+Rt*C*z/x (6)

The outputs OUT_T/OUT_B can be generated to null the skew difference by determining the values of the gate widths l, m, n, x, y, and z so as to satisfy the equation (6) above. However, since the gate widths l, m, n, x, y, and z are determined in the design stage before layout and manufacture of the circuit, they cannot be changed once determined. The conduction resistance Rt and the capacity C of the inverters are also fixed values which are determined according to the manufacturing processes and designing rule. In the actual design procedures, the values of the gate widths l, m, n, x, y, and z of the inverters are determined by simulation taking into consideration parasitic resistance and capacity of wiring lines and so on. However, the simulation is an approximate model involving a certain degree of assumption after all. If this approximate model deviates from an actual product, the relationship represented by the equation (6) cannot be satisfied and there occurs a skew difference between the two routes extending from the output IN_B of the inverter 101 to the outputs OUT_T and OUT_B.

Measures to correct such variation are frequently taken by preparing a plurality of load capacity elements of different sizes (for example, capacities z*C, z′*C, and z″*C) and replacing them with each other to optimize the characteristics after the manufacture of the circuit. This means that the optimization is achieved by adjusting the term of Rt*C*z/x in the equation (6). In this equation, the conduction resistance Rt is several kΩ, and the capacity C is in the order of several tens of fF (femto farad). These values are determined by manufacturing constraints, and thus they cannot be reduced after the design. In addition, the circuit is formed in as small size as possible in view of reducing the current consumption and limiting the increase of the chip surface area, and hence the gate width x cannot be set to a very large value. Accordingly, z/x can only assume a value close to one, and in the actual design, the value of Rt*C*z/x will be in the order of several tens of ps.

When a skew of several ps is to be adjusted in this complementary signal generation circuit, the adjustment is only possible by preparing load capacity elements having gate widths z, z′, and z″ which are mutually different by a small amount, and replacing the load capacity element having the gate width z with the load capacity element having the gate width z′ or with the load capacity element having the gate width z″. When load capacity elements of N in number are prepared for the skew adjustment, the number of adjustment combinations is N.

While in FIG. 7, an NMOS capacity element and a PMOS capacity element are provided as the load capacity elements, either one of an NMOS capacity element and a PMOS capacity element is provided in some cases for making it possible to perform fine adjustment. However, in the MOS capacity element, since the channel formation is inhibited as the gate-source voltage Vgs comes closer to the threshold voltage of the transistor, the MOS capacity element will become nonfunctional as the capacity element, which causes a problem that the amount of delay differs depending on the potential of nodes provided.

In order to solve this problem, the P-N ratio of the inverters within the circuit must be changed. However, this causes distortion in the signal waveform within the circuit, which in turn causes difficulty in optimizing characteristics in the entire manufacturing range, or causes increase in variation of circuit characteristics when the characteristics of the transistor varies in the manufacturing range.

A method of using a transfer gate is employed as one of techniques to avoid such a drawback caused by the use of capacity elements. An example of this technique is described in Japanese Laid-Open Patent Publication No. H11-150458 (Patent Document 2).

FIG. 9 is a circuit diagram for describing another related art of this invention and shows another example of a complementary signal generation circuit using a transfer gate. A transfer gate is used to connect the source and drain of a normally-on transistor to a propagation node, and a conduction resistance of the transistor is sometimes used as a delay element. In this case, in order to keep the transistor normally in the conduction state, the gate potential of the connected transistor 109 is fixed at the power supply potential if the transistor is an NMOS transistor, whereas if the transistor is a PMOS transistor, the gate potential is fixed at the ground potential VSS. However, since a signal line is connected to the source of the transistor 109, there occurs a difference in the amount of delay depending on signal potential. Specifically, in the case of an NMOS transistor, the gate-source voltage Vgs is decreased and the resistance is increased when the potential of the signal line is high. In the case of a PMOS transistor, the gate-source voltage Vgs is decreased and the resistance is increased when the potential of the signal line is low.

In view of these, it is a usual practice that a PMOS transistor and an NMOS transistor are used in pair for improvement of the characteristics. Even in this case, the resistance value becomes minimum when the potential of the signal line is at an intermediate level, and the resistance value tends to be increased (this means that the signal transition time tT is increased) as the potential of the signal line approaches either the power supply potential or the VSS potential. Moreover, this tendency is affected by the characteristics of the transistor. Consequently, this method has a shortcoming of being vulnerable to variation in the threshold voltage Vt of the transistor. Moreover, using this method, a plurality of (N) transfer gates having different sizes must be prepared for optimization after the manufacture. In this case, again, fine adjustment can only be performed by replacing the N transfer gates thus prepared, and thus only N combinations are available for the adjustment.

As is obvious from the description above, the present inventor has recognized that fine adjustment cannot be realized by usual skew adjustment methods using only capacity elements.

The present invention seeks to provide a complementary signal generation circuit capable of improving skew adjustment.

A complementary signal generation circuit according to a first aspect of this invention comprises first and second transmission paths. The first transmission path receives an input signal and includes a first number N of inverters. N is an integer greater than 2. The second transmission path receives the input signal and includes a second number (N−1) of inverters. A delay circuit composed of a first resistance element and a capacity element is arranged in series between two inverters in the second transmission path so as to correspond to any one of the inverters in the first transmission path. The capacity element is formed by a capacitive inverter having the same input capacity ratio as the any one of the inverters.

A complementary signal generation circuit according to a second aspect of this invention comprises first and second transmission paths. The first transmission path receives an input signal and is composed of a plural number of stages of inverters. The second transmission path receiving the input signal and is composed of a plural number of stages of inverters. The number of stages in the second transmission path is smaller by one than the number of the stages in the first transmission path. The second transmission path further includes a delay circuit composed of a capacity element and a first resistance element connecting between any two of the inverters. The delay circuit is arranged between a predetermined number-th stage inverter and the preceding stage inverter in the second transmission path so as to correspond to the predetermined number-th stage inverter in the first transmission path. The capacity element is formed by a capacitive inverter having the same input capacity ratio as that of the predetermined number-th stage inverter in the first transmission path.

The complementary signal generation circuits of the first and second aspects generate output signals having the logic levels which are complementary to each other through the first and second transmission paths.

According to a third aspect of this invention, a semiconductor device is provided. The semiconductor device comprises a Delay-Locked-Loop circuit that synchronizes data output with an external clock and a latch circuit for the data output controlled by complementary output signals from the Delay-Locked-Loop circuit. The Delay-Locked-Loop circuit comprises a first transmission path that receives an input signal and includes a first number N of inverters where N is an integer greater than 2 and a second transmission path that receives the input signal and includes a second number (N−1) of inverters. A delay circuit composed of a first resistance element and a capacity element is arranged in series between two inverters in the second transmission path so as to correspond to any one of inverters in the first transmission path. The capacity element is formed by a capacitive inverter having the same input capacity ratio as the any one of the inverters. The Delay-Locked-Loop circuit generates output signals having the logic levels which are complementary to each other through the first and second transmission paths.

According to this invention, a resistance element is arranged together with a capacity element in one of first and second transmission paths having a smaller number of delay stages formed by inverters, whereby fine adjustment is made possible for the skew between complementary signals.

Further, according to this invention, the resistance value of the resistance element to be arranged is set within a predetermined range, whereby effective skew reduction is enabled.

### BRIEF DESCRIPTION OF THE DRAWINGS

The above features and advantages of this invention will be more apparent from the following description of certain preferred embodiments taken in conjunction with the accompanying drawings, in which:

FIG. 1 is a diagram showing a complementary signal generation circuit according to a first embodiment of this invention;

FIG. 2 is a diagram showing a complementary signal generation circuit according to a second embodiment of this invention;

FIG. 3 is a diagram for explaining relationship between resistance value R of a resistance element provided in the complementary signal generation circuit shown in FIG. 2 and signal propagation time Td in a signal transmission path;

FIG. 4 is a timing chart diagram for explaining operation of the complementary signal generation circuit of FIG. 2;

FIG. 5 is a diagram showing a latch circuit as an application example of complementary signals;

FIG. 6 is a diagram showing relationship between frequencies and skew of control signals φ and /φ in the latch circuit shown in FIG. 5;

FIG. 7 is a diagram showing an example of a complementary signal generation circuit using capacity elements for skew adjustment;

FIG. 8 is a timing chart diagram for explaining operation of the complementary signal generation circuit of FIG. 7; and

FIG. 9 is a circuit diagram for explaining an example of a method of using transfer gates for skew adjustment.

### DESCRIPTION OF EXEMPLARY EMBODIMENTS

This invention will be described based on several exemplary embodiments.

### First Embodiment

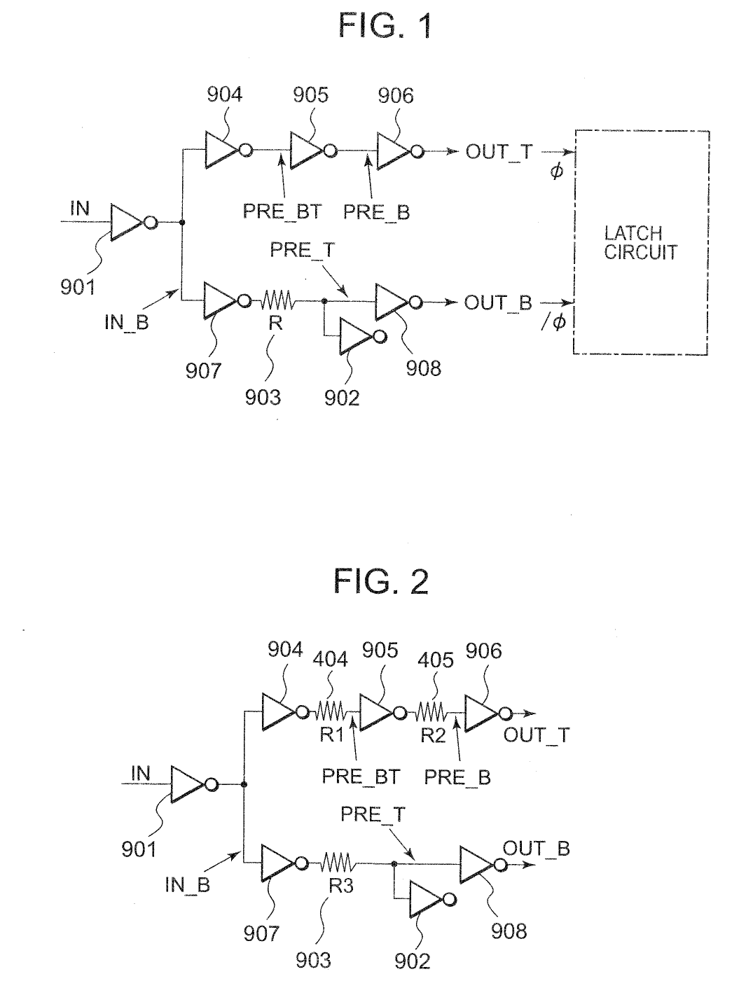

FIG. 1 shows a complementary signal generation circuit according to a first embodiment of this invention. The complementary signal generation circuit according to the first embodiment includes one input terminal IN and two output terminals OUT_T and OUT_B. A signal transmission path extending from the input terminal IN to one of the output terminals, that is, the output terminal OUT_T includes an even number of stages of inverters (a first number N (N is an integer greater than 2 (N>2)) of inverters) 901, 904, 905, and 906, while a signal transmission path extending from the input terminal IN to the other output terminal, that is, the output terminal OUT_B includes an odd number of stages of inverters (a second number (N−1) of inverters) 901, 907, and 908.

In the first embodiment, four stages of inverters are provided between the input terminal IN and the output terminal OUT_T, while three stages of inverters are provided between the input terminal IN and the output terminal OUT_B, and the inverter 901 is used in common as the first inverter in both the signal transmission paths. However, the first inverter need not necessarily be used in common, as long as one of the two signal transmission paths is provided with an even number of stages of inverters while the other signal transmission path is provided with an odd number of stages of inverters. In the signal transmission path between the input terminal IN and the output terminal OUT_B, the inverter (capacitive inverter) 902 which is provided being branched from the anode side of the inverter 908 and has an open output end is a capacity element for adjusting skew between the signal transmission path having the even number of stages of inverters and the signal transmission path having the odd number of stages of inverters. Although this capacity element may be provided by a PMOS capacity element or NMOS capacity element as described in FIG. 7, better characteristics can be obtained by using an inverter element having the same P-N ratio as the inverter elements on the other signal transmission path so that the “L” to “H” transition time tT and the “H” to “L” transition time tT at the node PRE T are equal to each other. The term “P-N ratio” as used herein means a ratio between input capacities which are parasitic capacities of the PMOS transistor and the NMOS transistor.

FIG. 1 shows a configuration in which the reference numeral 902 indicates an inverter element. In the circuit of FIG. 1, two signal transmission paths have four stages of inverters and three stages of inverters, respectively. Thus, the circuit is designed to delay the transmission rate of the signal transmission path having three stages of inverters and thus having a higher transmission rate. If four stages of inverters are provided between IN and OUT_T while five stages of inverters are provided between IN and OUT_B, the transmission rate of the path with four stages inverters becomes higher. In this case, the capacity element (inverter) 902 is provided on the path extending between IN and OUT_T.

In the first embodiment, a resistance element 903 (first resistance element) is additionally connected to (inserted into) the signal transmission path having the capacity element 902 connected thereto. The resistance element 903 is a resistance element formed by a diffusion layer resistance or metallic resistance. A delay circuit is formed by the resistance element 903 (first resistance element) and the inverter 902 (capacitive inverter). The inverter 902 (capacitive inverter) exhibits effects which are different from and better than those of the load capacity elements 107 and 108 according to the related art (FIG. 7). Specifically, the inverter 902 (capacitive inverter) performs the same function as pass-through current which flows when the input signal of the associated inverter 905 varies (transits), and thus has the same effects as the transition of the parasitic capacity value that occurs in the gate of the inverter 905 when the input signal rises and falls.

### Explanation of Manufacture (Process etc.) or Operation (Circuit etc.) of First Embodiment

Basic circuit operation of the complementary signal generation circuit according to the first embodiment is the same as described in the section “Description of the Related Art”.

### Effect of First Embodiment

Referring to FIG. 1, description will be made of the possibility of fine skew adjustment that is realized by the use of the resistance element 903 for the skew adjustment. In the same manner as described in FIG. 7, the inverters 904, 905, 906, 907, 908, and 902 in FIG. 1 also have gate widths of l, m, n, x, y, and z, respectively. If the gate capacity of each inverter per unit gate width is represented by C, the gate capacities of the inverters 904, 905, 906, 907, 908, and 902, which are proportional to the gate widths, can be represented as l*C, m*C, n*C, x*C, y*C, and z*C, respectively. Likewise, if the conduction (ON) resistance of each inverter per unit gate width is represented by Rt, the conduction (ON) resistances of the inverters 904, 905, 906, 907, 908, and 902, which are inversely proportional to the gate widths, can be represented as Rt/l, Rt/m, Rt/n, Rt/x, Rt/y, and Rt/z, respectively. Further, the unit resistance of the resistance element is represented by Rm, and the resistance value of the resistance element 903 is represented by r*Rm. Since the resistance element 903 is formed by a diffusion layer resistance or metallic resistance, the resistance value will be changed neither by variation in the threshold value of the transistor, nor by the signal potential. Thus, the distortion in the transition time tT will not occur.

Accordingly, the signal propagation time T_t of the signal transmission path from the output IN_B to the output terminal OUT_T can be represented by the following equation (7).

$$\begin{matrix}T\_t = tTR + ( Rt / l ) {m}^{*} C + tTR + ( Rt / m ) {n}^{*} C + tTR \\ = 3 tTR + {Rt}^{*} C ( m / l + n / m )\end{matrix} \qquad ( 7 )$$

On the other hand, the signal propagation time T_b of the signal transmission path from the output IN_B to the output terminal OUT_B can be represented by the following equation (8).

$$\begin{matrix}T\_b = tTR + ( Rt / x + {r}^{*} Rm ) ( {y}^{*} C + {z}^{*} C ) + tTR \\ = 2 tTR + {Rm}^{*} C ( {r}^{*} y + {r}^{*} z ) + {Rt}^{*} C ( y / x + z / x )\end{matrix} \qquad ( 8 )$$

In the complementary signal generation circuit, the difference T in the signal propagation time between the path from the output IN_B to output terminal OUT_T and the signal propagation time of the path from the output IN_B to the output terminal OUT_B can be represented by the following equation (9).

$$\begin{matrix}T = T\_t - T\_b \\ = tTR - \{ {Rm}^{*} C ( {r}^{*} y + {r}^{*} z ) + {Rt}^{*} C ( y / x + z / x - m / l - n / m ) \}\end{matrix} \qquad ( 9 )$$

If it is assumed here that the difference in the signal propagation time between these two paths is zero, that is T=0, the following equation (10) is obtained.

tTR=Rt*C(y/x+z/x−m/l−n/m)+Rm*C(r*y+r*z) (10)

The value of the first term of the right-side member of the equation (10) is a fixed value determined by the manufacturing process and preliminary design, while the second term of the right-side member is a variable that can be adjusted after manufacture.

Generally, the conduction (ON) resistance Rt as the resistance during conduction of the transistor is in the order of several kΩ. In contrast, as for the resistance element 903 used in the first embodiment, only the sheet resistance is determined by the manufacturing process, whereas the resistance value can be determined freely according to the length and width, and hence it can be set to a value lower than the conduction resistance Rt of the transistor, for example in the range of 1 to 1000Ω, and preferably in the range of 10 to 1000Ω.

Accordingly, the second term of the right-side member of the equation (10) can be a very small value such as several hundreds of fs (femto second) or several tens of ps. Moreover, by preparing N resistances of several Ω to several hundreds of Ω, an incomparably greater variety of adjustment combinations (2^{N} different adjustment combinations) than the usual capacity adjustment type can be provided. However, in reality, the resistance elements also suffer variation in characteristics caused by manufacturing factors. If it is assumed that the unit resistance Rm varies by ΔRm, the skew will be offset by ΔRm*C(r*y+r*z) in the circuit employing the resistance elements for skew adjustment according to the first embodiment. However, since the unit resistance Rm itself is a resistance producing several ps to several tens of ps, the skew offset caused by the variation of ΔRm (<Rm) can be limited to about one to ten ps.

The complementary signal generation circuit according to the first embodiment of this invention, as described above, has the resistance element and the capacity element arranged in the signal transmission path having a smaller number of delay stages, and this enables the fine adjustment of the skew between the complementary signals obtained from the two signal transmission paths.

When the complementary signal generation circuit is for generating complementary signals within a DLL (Delay-Locked-Loop) circuit, output signals from the output terminals OUT_T and OUT_B become control signals φ and /φ to a latch circuit as described in FIG. 5.

Referring to FIG. 10, description will be made on the capacitive inverter 902. FIG. 10 shows an example of a capacitive inverter configuration. The capacitive inverter 902 is composed of a first conductivity type field-effect transistor Tr1 and a second conductivity type field-effect transistor Tr2. A first power supply PS1 is connected to the source S of the field-effect transistor Tr1, and the drain D of the field-effect transistor Tr2 is connected to the drain D of the field-effect transistor Tr1. A second power supply PS2 is connected to the source S of the field-effect transistor Tr2, and the drain D of the field-effect transistor Tr1 is connected to the drain D of the field-effect transistor Tr2. The gates G of the field-effect transistors Tr1 and Tr2 are connected to each other and connected to a node PRE_T, and the output of the capacitive inverter 902 is open. When MOS transistors are used, the sources and drains of the transistors Tr1 and Tr2 shown in FIG. 10 are formed by a diffusion layer, and the gates are formed by electrodes formed on an insulation layer. It should be understood that the configuration of the capacitive inverter is not limited to the one shown in FIG. 10.

### Second Embodiment

FIG. 2 shows a complementary signal generation circuit according to a second embodiment of this invention. In the second embodiment, a first resistance element 403, a second resistance element 404, and a third resistance element 405 are used as the resistance elements. In this embodiment, the resistance elements are provided in both the paths extending from the output IN_B to the output terminal OUT_T and the output terminal OUT_B. Since the resistance elements have variation in characteristics caused by manufacturing factors, the skew variation caused by the variation in characteristics can be reduced more than the first embodiment by the arrangement of the resistance elements in the two paths. The configuration and operation of the second embodiment is the same as those of the first embodiment except the resistance elements 403, 404, and 405.

### Effects of Second Embodiment

In the second embodiment, the resistance element is provided not only in the path from the output IN_B to the output terminal OUT_B but also in the path from the output IN_B to the output terminal OUT_T, whereby the characteristics are improved. This effect will be described below.

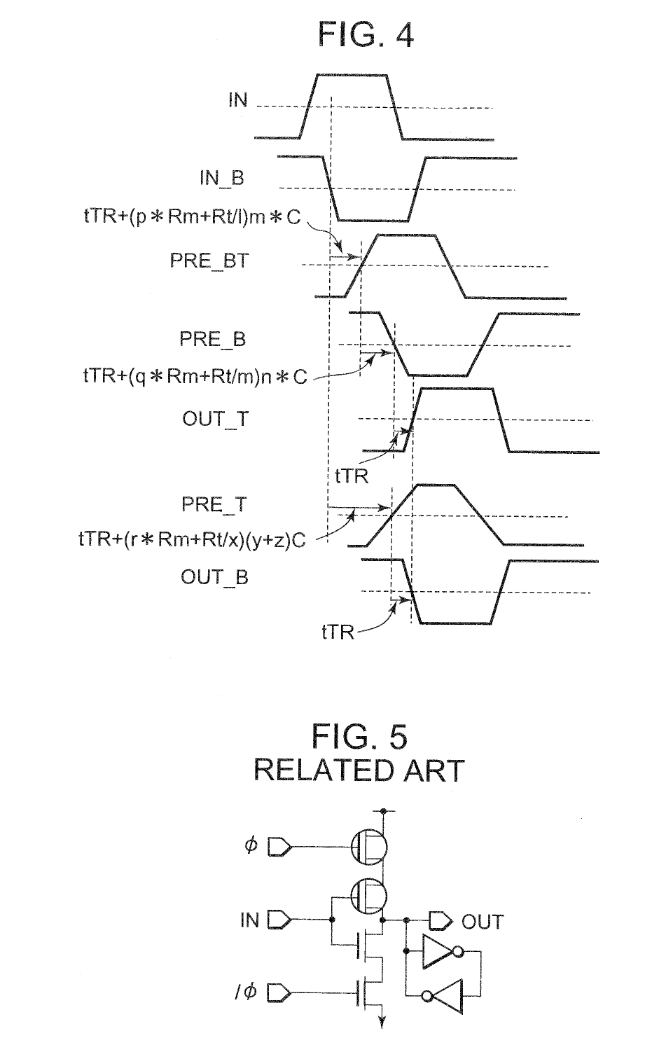

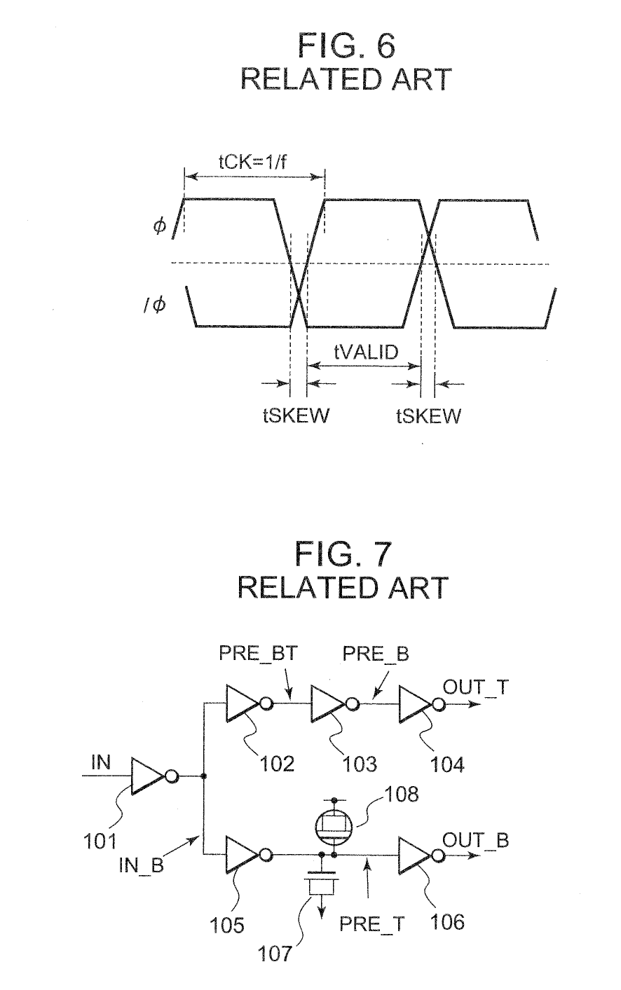

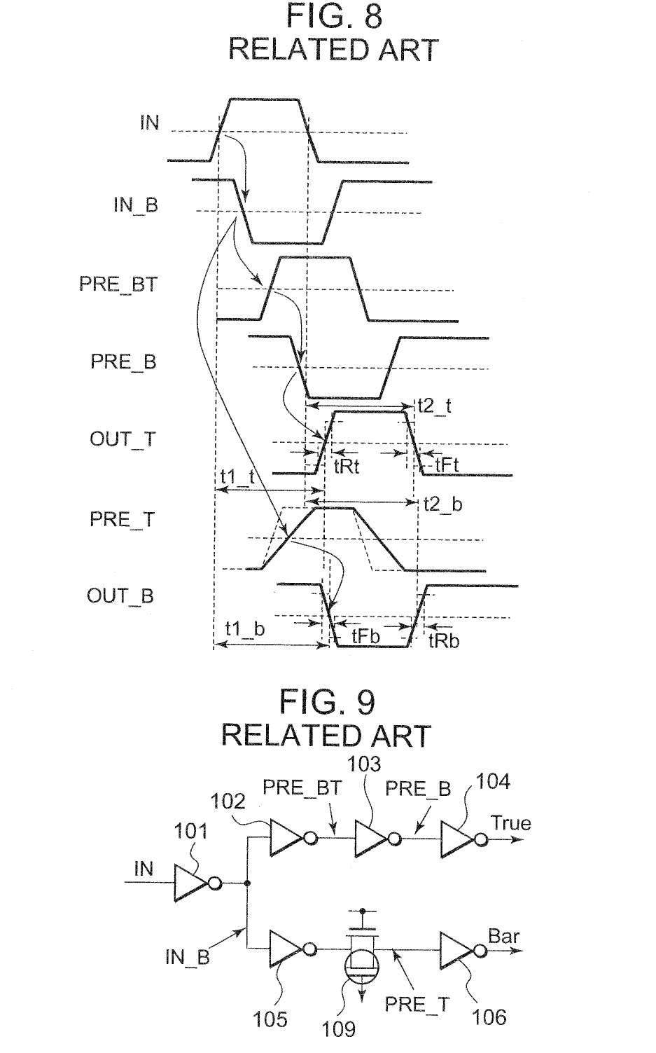

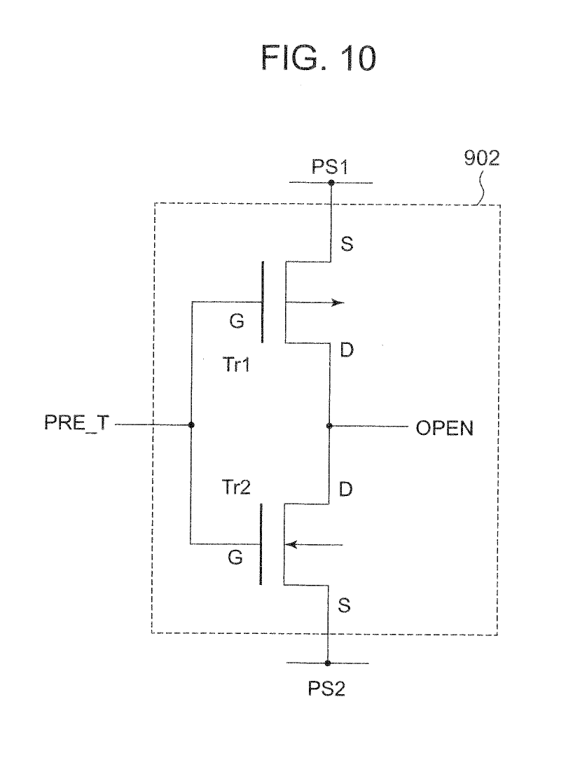

The effect of the complementary signal generation circuit according to the second embodiment will be described with reference to FIGS. 2 and 4. Here, the resistance values of the resistance elements 404, 405, and 403 in FIG. 2 are represented by p*Rm, q*Rm, and r*Rm, respectively, and the gate widths of the inverters 904, 905, 906, 907, 908, and 902 are represented by l, m, n, x, y, and z, respectively. Then, the gate capacities of the inverters can be represented as l*C, m*C, n*C, x*C, y*C, and z*C in the same manner as described above. The conduction (ON) resistances of the inverters can be represented as Rt/l, Rt/m, Rt/n, Rt/x, Rt/y, and Rt/z, respectively. The signal propagation time T_t of the path from the output IN_B to the output terminal OUT_T can be represented by the following equation (11).

$$\begin{matrix}T\_t = tTR + ( Rt / l + {p}^{*} Rm ) {m}^{*} C + tTR + \\ ( Rt / m + {q}^{*} Rm ) {n}^{*} C + tTR \\ = 3 tTR + {Rm}^{*} C ( {p}^{*} m + {q}^{*} n ) + {Rt}^{*} C ( m / l + n / m )\end{matrix} \qquad ( 11 )$$

On the other hand, the signal propagation time T_b of the path from the output IN_B to the output terminal OUT_B can be represented by the following equation (12).

$$\begin{matrix}T\_b = tTR + ( Rt / x + {r}^{*} Rm ) ( {y}^{*} C + {z}^{*} C ) + tTR \\ = 2 tTR + {Rm}^{*} C ( {r}^{*} y + {r}^{*} z ) + {Rt}^{*} C ( y / x + z / x )\end{matrix} \qquad ( 12 )$$

In this complementary signal generation circuit, the difference T in the signal propagation time between the path from the output IN_B to the output terminal OUT_T and the path from the output IN_B to the output terminal OUT_B is represented by the following equation (13).

T=T_{—}t−T_{—}b=tTR−{Rm*C(r*y+r*z−p*m−q*n)+Rt*C(y/x+z/x−m/l−n/m)} (13)

If it is assumed here that the difference in the signal propagation time between the two paths is zero, that is T=0, the following equation (14) is obtained.

tTR=Rm*C(r*y+r*z−p*m−q*n)+Rt*C(y/x+z/x−m/l−n/m) (14)

If substitution is made as follows in the equation (14) above,

k=r*y+r*z−p*m−q*n (15)

h=y/x+z/x−m/l−n/m (16)

then the equation (14) is replaced by the following equation (17).

tTR=k*C*Rm+h*C*Rt (17)

In the equation (17) above, k must be greater than zero (k>O). This is because, if k=0, the term in the equation (17) representing the unit resistance Rm is nullified, and it becomes meaningless to use the resistance elements. Further, if k is smaller than zero (k<0), h*C*Rt is greater than tTR (h*C*Rt>tTR) based on the equation (17), and thus the amount of delay caused by the capacity element is increased, resulting in loss of overall speed.

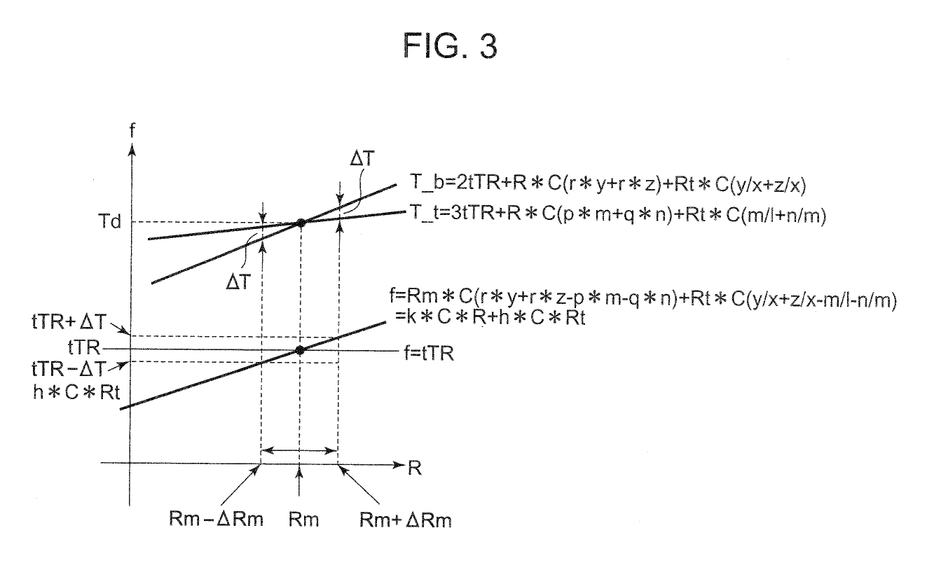

As seen from FIG. 3, the equation (17) indicates that a straight line of f=tTR intersects with a straight line of f=k*C*R+h*C*Rt at an intersection of R=Rm. When the equation (17) is assigned to the equation (11) or (12), the following equation (18) relating to the signal propagation time is obtained.

Td=T_{—}t=T_{—}b=Rm*C(2r*y+2r*z−p*m−q*n)+Rt*C(2y/x+2z/x−m/l−n/m) (18)

Since the manufacturing variations cannot be eliminated, the actual unit resistance Rm is not a fixed value but distributed around the central value of Rm. Such variation in the unit resistance Rm produces a difference in signal propagation time between the two signal transmission paths in the complementary signal generation circuit. If it is assumed here that the unit resistance Rm varies by ±ΔRm around the central value Rm, a difference of ±ΔT in the signal propagation time represented by the following equation (19) is produced based on the equation (13).

±ΔT=±ΔRm*C(r*y+r*z−p*m−q*n)=±ΔRm*Ck (19)

In the second embodiment, the resistance elements are inserted in both of the two signal transmission paths, specifically, the resistance elements 404 and 405 are inserted in the path extending from the output IN_B to the output terminal OUT_T and the resistance element 403 is inserted in the path extending from the output IN_B to the output terminal OUT_B. In comparison with the first embodiment in which the resistance element is inserted only in the path extending from the output IN_B to the output terminal OUT_B (p=q=0), the second embodiment reduces the variation in signal propagation time by ΔRm*C(p*m+q*n), which enables even more accurate skew adjustment.

While the variable range of ΔRm depends on a material used for the resistance elements, it is generally about 10 to 20% of a set value of the resistance value. The conduction (ON) resistance Rt of the transistor is in the order of several kΩ. In contrast, as for the resistance elements 404 and 405 used in the second embodiment, only the sheet resistance is determined by the manufacturing process, whereas the resistance value can be determined freely according to length and width. Therefore, the resistance elements 404 and 405 used in the second embodiment can produce a small resistance of 1 to 1000Ω, preferably of 10 to 1000Ω, that is smaller than the conduction resistance Rt of the transistor. When the resistance value of the resistance elements 404 and 405 in FIG. 2 is set to 1000Ω or lower (1 to 10000), the magnitudes of p*ΔRm and q*ΔRm are 0.1 to 200. Since the capacity C is in the order of several tens of fF, the ΔRm*C(p*m+q*n) is in the order of several ps, and thus the manufacturing variation of the resistance elements can be substantially eliminated.

In the complementary signal generation circuit according to the second embodiment of this invention, as described above, resistance elements are arranged not only in the signal transmission path having a smaller number of delay stages but also in the signal transmission path having a greater number of delay stages, whereby the variation in the resistance values of the resistance elements is reduced, making it possible to perform the fine skew adjustment more accurately.

Although this invention has been described with reference to the two exemplary embodiments thereof, this invention is not limited to these embodiments. It will be understood by those skilled in the art that various modifications and changes can be made in form and details of this invention without departing from the spirit and scope of the invention. For example, it is intended to cover in the appended claims not only the complementary signal generation circuits but also other semiconductor integrated circuits having such a complementary signal generation circuit.

The transistor can be any field-effect transistor (FET). In addition to MOS (Metal Oxide Semiconductor) transistors, various other FETs such as MIS (Metal-insulator Semiconductor) transistors can be used. PMOS transistors (P-type channel MOS transistors) are a typical example of first conductivity type transistors, while NMOS transistors (N-type channel MOS transistors) are a typical example of second conductivity type transistors.

What is claimed is:

1. A complementary signal generation circuit comprising:
a first transmission path that receives an input signal and includes a first number N of inverters where N is an integer greater than 2; and
a second transmission path that receives the input signal and includes a second number (N−1) of inverters, wherein:
a delay circuit composed of a first resistance element and a capacity element is arranged in series between two inverters in the second transmission path so as to correspond to any one of the inverters in the first transmission path;
the capacity element is formed by a capacitive inverter having the same input capacity ratio as the any one of the inverters; and
respective output signals from the first and second transmission paths are signals that their logic levels are complementary to each other.

2. The complementary signal generation circuit as claimed in claim 1, wherein in the delay circuit, one end of the first resistance element is connected to the output of the preceding stage inverter, the other end of the first resistance element is connected to the gate of the capacitive inverter, and the output of the capacitive inverter is open.

3. The complementary signal generation circuit as claimed in claim 1, wherein:
the capacitive inverter is composed of a first conductivity type field-effect transistor and a second conductivity type field-effect transistor;
the first conductivity type field-effect transistor is connected to a first power supply at the source thereof, and to the drain of the second conductivity type field-effect transistor at the drain thereof;
the second conductivity type field-effect transistor is connected to a second power supply at the source thereof, and to the drain of the first conductivity type field-effect transistor at the drain thereof;
the gates of the first conductivity type and second conductivity type field-effect transistors are connected to each other; and
the output of the capacitive inverter is open.

4. The complementary signal generation circuit as claimed in claim 1, wherein the resistance value of the first resistance element is smaller than the conduction resistance per unit gate width of the transistors forming the inverters.

5. The complementary signal generation circuit as claimed in claim 4, wherein the resistance value of the first resistance element is from 1 to 1000φ.

6. The complementary signal generation circuit as claimed in claim 4, wherein the first resistance element is formed by a diffusion layer resistance or a metallic resistance.

7. The complementary signal generation circuit as claimed in claim 2, wherein the difference between the transmission time required to transfer a signal from the input to the output through the first transmission path and the transmission time required to transfer a signal from the input to the output through the second transmission path is in the range from 1 to 10 ps.

8. The complementary signal generation circuit as claimed in claim 2, wherein a second resistance element is connected to each of the input and the output of the any one of the inverters.

9. The complementary signal generation circuit as claimed in claim 8, wherein the resistance value of the second resistance element is smaller than the conduction resistance per unit gate width of the transistors forming the inverters.

10. The complementary signal generation circuit as claimed in claim 9, wherein the resistance value of the second resistance element is from 1 to 1000φ.

11. The complementary signal generation circuit as claimed in claim 8, wherein:
the first transmission path includes a first, second, and third inverters, and a plurality of the second resistance elements;
the second transmission path includes a fourth and fifth inverters, the first resistance element, and the capacitive inverter;
one of the second resistance elements is arranged between the output of the first inverter and the input of the second inverter;
another one of the second resistance elements is arranged between the output of the second inverter and the input of the third inverter; and
the first resistance element and the capacitive inverter are arranged between the output of the fourth inverter and the input of the fifth inverter.

12. The complementary signal generation circuit as claimed in claim 11, wherein the absolute value of variation in resistance during manufacturing of the second resistance element is 10 to 20% of a set value in resistance of the second resistance element.

13. The complementary signal generation circuit as claimed in claim 1, wherein the complementary signal generation circuit generates complementary signals in a Delay-Locked-Loop circuit.

14. A complementary signal generation circuit comprising:
a first transmission path that receives an input signal and is composed of a plural number of stages of inverters; and
a second transmission path that receives the input signal and is composed of a plural number of stages of inverters, the number being smaller by one than the number of the stages in the first transmission path, the second transmission path further including a delay circuit composed of a capacity element and a first resistance element connecting between any two of the inverters, wherein:
the delay circuit is arranged between a predetermined number-th stage inverter and the preceding stage inverter in the second transmission path so as to correspond to the predetermined number-th stage inverter in the first transmission path;
the capacity element is formed by a capacitive inverter having the same input capacity ratio as that of the predetermined number-th stage inverter in the first transmission path; and
respective output signals from the first and second transmission paths are signals that their logic levels are complementary to each other.

15. The complementary signal generation circuit as claimed in claim 14, wherein in the delay circuit, one end of the first resistance element is connected to the output of the preceding stage inverter, the other end of the first resistance element is connected to the gate of the capacitive inverter, and the output of the capacitive inverter is open.

16. The complementary signal generation circuit as claimed in claim 14, wherein the capacitive inverter is composed of a first conductivity type field-effect transistor and a second conductivity type field-effect transistor;
the first conductivity type field-effect transistor is connected to a first power supply at the source thereof, and to the drain of the second conductivity type field-effect transistor at the drain thereof;
the second conductivity type field-effect transistor is connected to a second power supply at the source thereof, and to the drain of the first conductivity type field-effect transistor at the drain thereof; and
the gates of the first conductivity type and second conductivity type field-effect transistors are connected to each other.

17. A semiconductor device comprising:
a Delay-Locked-Loop circuit that synchronizes data output with an external clock; and
a latch circuit for the data output controlled by complementary output signals from the Delay-Locked-Loop circuit, wherein:
the Delay-Locked-Loop circuit comprises:
a first transmission path that receives an input signal and includes a first number N of inverters where N is an integer greater than 2; and
a second transmission path that receives the input signal and includes a second number (N−1) of inverters;
a delay circuit composed of a first resistance element and a capacity element is arranged in series between two inverters in the second transmission path so as to correspond to any one of inverters in the first transmission path;
the capacity element is formed by a capacitive inverter having the same input capacity ratio as the any one of the inverters; and
the Delay-Locked-Loop circuit generate output signals having logic levels which are complementary to each other through the first and second transmission paths.

18. The semiconductor device as claimed in claim 17, wherein in the delay circuit, one end of the first resistance element is connected to the output of the preceding stage inverter, the other end of the first resistance element is connected to the gate of the capacitive inverter, and the output of the capacitive inverter is open.

19. The semiconductor device as claimed in claim 17, wherein:
the capacitive inverter is composed of a first conductivity type field-effect transistor and a second conductivity type field-effect transistor;
the first conductivity type field-effect transistor is connected to a first power supply at the source thereof, and to the drain of the second conductivity type field-effect transistor at the drain thereof;
the second conductivity type field-effect transistor is connected to a second power supply at the source thereof, and to the drain of the first conductivity type field-effect transistor at the drain thereof;
the gates of the first conductivity type and second conductivity type field-effect transistors are connected to each other; and
the output of the capacitive inverter is open.
